(19) United States
(12) Patent Application Publication
(10) Pub. No.: US 2023/0084779 A1
(43) Pub. Date: Mar. 16, 2023

(54) BATTERY SYSTEM AND PROTECTION METHOD THEREOF

(71) Applicant: INDUSTRIAL TECHNOLOGY RESEARCH INSTITUTE, Hsinchu (TW)

(72) Inventors: Chein-Chung SUN, Kaohsiung City (TW); Chi-Hua CHEN, Zhubei City (TW); Chun-Hung CHOU, Tainan City (TW); Si-Yu FU, Taichung City (TW)

(73) Assignee: INDUSTRIAL TECHNOLOGY RESEARCH INSTITUTE, Hsinchu (TW)

(21) Appl. No.: 17/557,892

(22) Filed: Dec. 21, 2021

(30) Foreign Application Priority Data
Sep. 11, 2021 (TW) 110133912

(51) Int. Cl. H02J 7/00; G01R 31/396; G01R 31/382

(52) U.S. Cl. CPC H02J 7/00302; H02J 7/0013; H02J 7/00036; H02J 7/0048; H02J 7/00712; G01R 31/396; G01R 31/382

(57) ABSTRACT

A battery system includes several unit battery groups, a main switch, a current measuring unit, several slave control units and a master control unit. Each unit battery group includes several cells. The main switch and the current measuring unit are serially connected to the unit battery groups. The current measuring unit measures a measured system current value of the unit battery groups. The slave control units are electrically connected to the unit battery groups respectively. Each slave control unit measures a physical parameter value of each cell in each unit battery group. The master control unit communicates with the slave control units to: disconnect the main switch when the abnormality determined according to the physical parameter value or the measured system current value pertains to system abnormality; and, perform a processing procedure for detection abnormality when the abnormality pertains to detection abnormality.

This application claims the benefit of Taiwan application Serial No. 110133912, filed Sep. 11, 2021, the subject matter of which is incorporated herein by reference.

### BACKGROUND

### Technical Field

The disclosure relates in general to a battery system and a protection method thereof.

### Description of the Related Art

As the issue of air pollution is attracting greater and greater attention, the urge for substituting petrochemical energy has prompted booming development in the hybrid or pure electric automotive industries in which battery system is a crucial and indispensable element. During the process of providing an electric current to the load, the battery system needs to continuously inspect whether any abnormality occurs. When an abnormality occurs, the battery system needs to take a corresponding measure to avoid the battery system and/or the load being damaged.

However, the current protection mechanism of the battery system is immediately activated should any abnormality signal be detected, and the calculations of determination are centralized and performed by a master control unit. Under such design, the master control unit has a heavy workload of calculation.

Therefore, it has become a prominent task for the industries to provide a battery system and a protection method thereof capable of resolving the problems encountered in the prior art.

### SUMMARY

The disclosure is directed to a battery system and a battery system protection method thereof.

According to one embodiment of the present disclosure, a battery system including several unit battery groups, a main switch, a current measuring unit, several slave control units and a master control unit is provided. Each unit battery group includes a plurality of cells serially connected to each other, and the plurality of unit battery groups connected in series with each other. The main switch and the current measuring unit are serially connected to the unit battery groups to measure a measured system current value of the unit battery groups. The slave control units are electrically connected to the unit battery groups respectively, wherein each slave control unit is configured to measure a physical parameter value of each cell in each unit battery group. The master control unit is connected to the slave control units through communication to disconnect to the main switch when the abnormality determined according to the physical parameter value or the measured system current value pertains to system abnormality; and, perform a processing procedure for detection abnormality when the abnormality determined according to the physical parameter value or the measured system current value pertains to detection abnormality.

According to another embodiment of the present disclosure, a protection method of a battery system is provided. The battery system is as disclosed above. The protection method includes the following steps: measuring a measured system current value of the unit battery groups by a current measuring unit; measuring a physical parameter value of each cell in the corresponding unit battery group by each cell; disconnecting to a main switch by a master control unit when the abnormality determined according to the physical parameter value or the measured system current value pertains to system abnormality; and, performing a processing procedure for detection abnormality by the master control unit when the abnormality determined according to the physical parameter value or the measured system current value pertains to detection abnormality.

The following descriptions of the preferred but non-limiting embodiment(s) are to enhance the understanding. The following description is made regarding the accompanying drawings.

### BRIEF DESCRIPTION OF THE DRAWINGS

FIG. 1A is a schematic diagram of a battery system according to an embodiment of the present disclosure.

FIG. 16 is a flowchart of a protection method of the battery system of FIG. 1A.

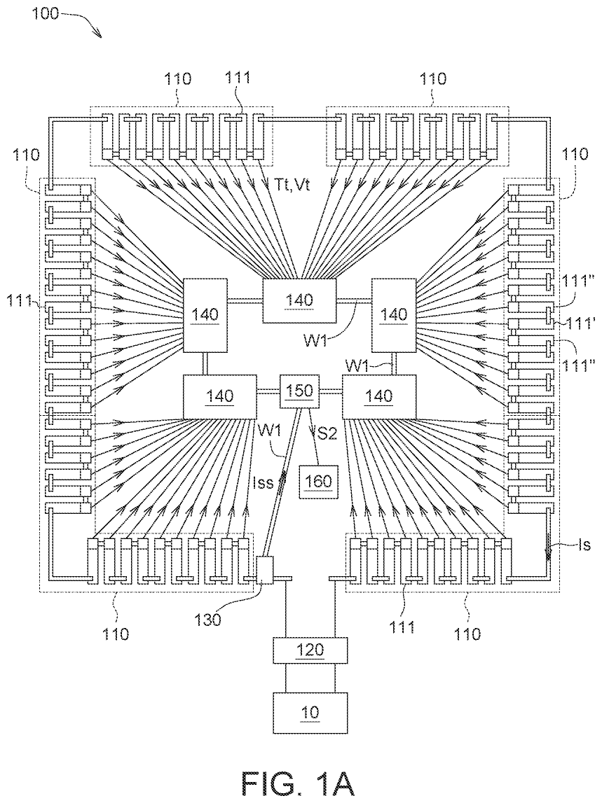

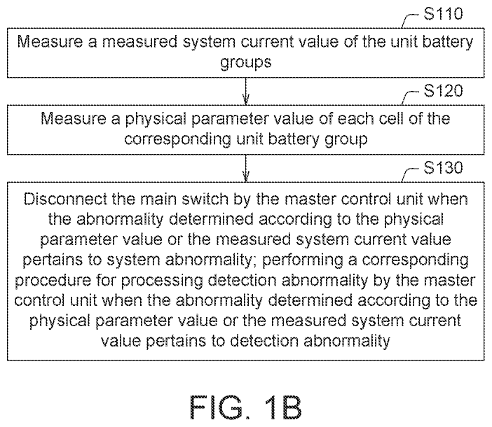

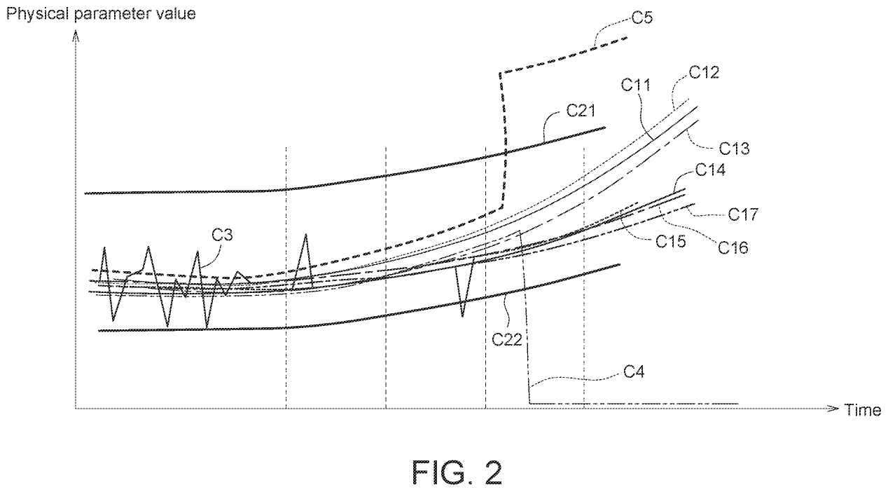

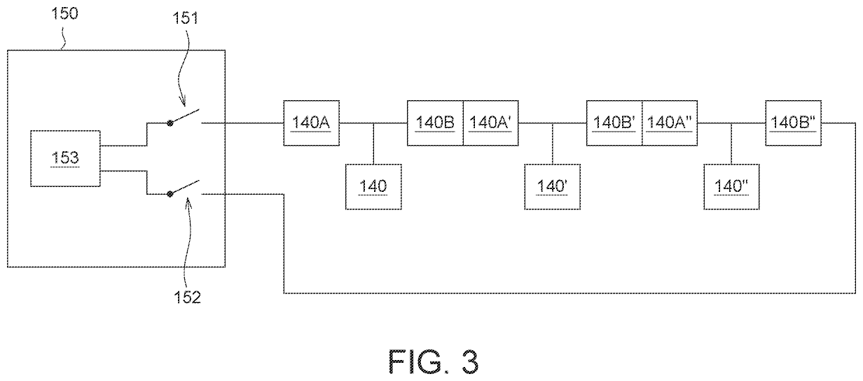

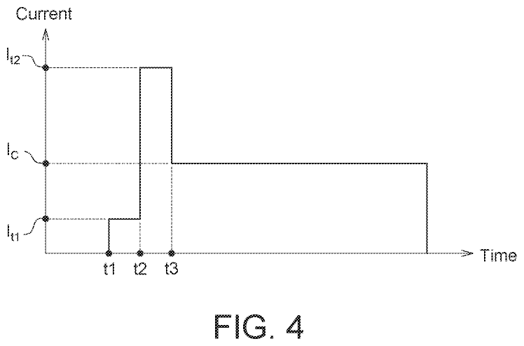

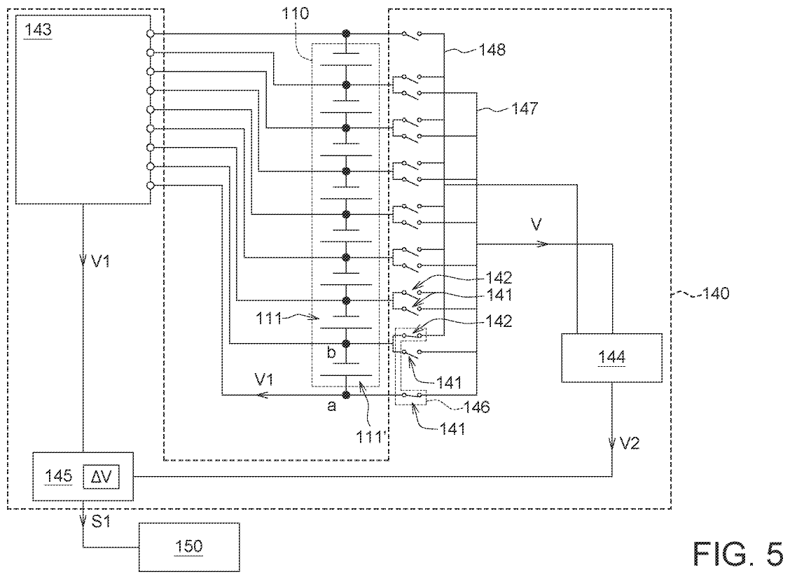

FIG. 2 is a curve chart of physical parameters obtained under different abnormalities of the battery system of FIG. 1A.

FIG. 3 is a schematic diagram of several slave control units serially connected to a master control unit according to an embodiment of the present disclosure.

FIG. 4 is a current change chart of a charger providing power to a battery system according to an embodiment of the present disclosure.

FIG. 5 is a schematic diagram of the slave control units of FIG. 1A and the cell connected thereto.

### DETAILED DESCRIPTION

FIG. 1A is a schematic diagram of a battery system 100 according to an embodiment of the present disclosure. FIG. 1B is a flowchart of a protection method of the battery system 100 of FIG. 1A. FIG. 2 is a curve chart of physical parameters obtained under different abnormalities of the battery system 100 of FIG. 1A.

The battery system 100 includes several unit battery groups 110, a main switch 120, a current measuring unit 130, several slave units 140 and a master unit 150. Each unit battery groups 110 includes several serially connected cells 111. The unit battery groups 110 are connected in series with each other as a serially connected battery group to increase the working voltage of the battery system 100. The main switch 120 is serially connected to the unit battery groups 110 to control the power output and power input of the serially connected battery group. The current measuring unit 130 is serially connected to the unit battery groups 110 to measure a measured system current value Iss of the unit battery groups 110 (or serially connected battery group). The slave control units 140 are electrically connected to the unit battery groups 110 respectively, wherein each slave control unit 140 is configured to obtain a physical parameter value of each cell 111 in the corresponding unit battery groups 110. The master control unit 150 is connected to the slave control units through communication 140 to: (1) disconnect to the main switch 120 when the abnormality determined according to the physical parameter value or the measured system current value Iss pertains to system abnormality; and (2) perform a processing procedure for processing detection abnormality when the abnormality determined according to the physical parameter value or the measured system current value Iss pertains to detection abnormality. In the present embodiment, the result of abnormality determination according to the physical parameter value is provided by the slave control units 140, such that the workload of the master control unit 150 could be reduced greatly. It should be noted that the measured system current value Iss refers to the current value reported to the master control unit 150 by the current measuring unit 130.

To put it in more detail, the battery system 100 of the embodiments of the present disclosure obtains the physical parameter value of several cells 111 respective from several slave control units 140 and then performs abnormality determination according to the obtained physical parameter values. The battery system 100 of the embodiments of the present disclosure pertains to decentralized calculation battery system.

The current measuring unit 130, the slave control units 140 and the master control unit 150 could be realized by a physical circuit formed of electronic elements or realized by an integrated circuit such as a semiconductor chip or a semiconductor package formed using semiconductor packaging process. The slave control units 140 could be arranged on a circuit board (not illustrated), and the master control unit 150 could be arranged on another circuit board (not illustrated). Or, the slave control units 140 and the master control unit 150 could be arranged on the same circuit board (not illustrated).

Examples of the physical parameter value disclosed above include a measured voltage value Vt and/or a measured temperature value Tt of each cell 111 connected to the unit battery groups 110, wherein the measured voltage value Vt and/or the measured temperature value Tt are detected by the slave control units 140. Examples of the detection abnormality disclosed above include the abnormalities caused by short-circuiting, signal wire breaking, or noises. Detection abnormalities substantially do not incapacitate the battery system 100 (the failure mode such as burning out or overloading that could substantially damage the battery system 100). Examples of the system abnormality disclosed above include abnormalities occurring to the cell, the slave control units 140 or the master control unit 150. System abnormalities may substantially incapacitate the battery system 100 (causing substantially damage such as burning out or overloading the battery system). In the present embodiment, the slave control units 140 mainly measure the physical value of voltage and temperature and performs calculation and determination according to the measured data; the master control unit 150 verifies the determination result received from the slave control units 140 and controls the switching of the main switch 120. A few functions that cannot be determined by the slave control units 140, such as the current detection abnormality or the system abnormality caused by over-current, are determined by the master control unit 150, such that the workload of the master control unit 150 could be reduced greatly. In other words, most of the calculations in the measurement and determination of the entire battery system 100 are shared by the slave control units 140. The master control unit 150 only or mainly performs a small number of determinations and the switching of the main switch 120, such that the workload could be reduced greatly.

In the present embodiment, the current measuring unit 130, after measuring the measured system current value Iss, transmits the measured system current value Iss to the master control unit 150, which then calculates the measured system current value Iss and performs abnormality determination according to the measured system current value Iss and at the same time broadcasts the current value Iss to the slave control units 140 to assist the slave control units 140 with the calculation and determination in the abnormality detection of voltage and temperature. In other embodiments, if the current measuring unit 130 could perform data calculation, then the current measuring unit 130, after measuring the measured system current value Iss, could directly perform calculation and abnormality determination and then transmit the measured system current value Iss and the result of abnormality determination to the master control unit 150. Detailed implementations are not limited to the above exemplifications.

Although it is not illustrated, each cell 111 includes a voltage measurer and a temperature measurer. The slave control units 140 could obtain each measured voltage value Vt from the slave voltage measurer and obtain each measured temperature value Tt from the temperature measurer. The slave control units 140 could perform abnormality determination according to the measured voltage value Vt and/or the measured temperature value Tt of at least one of the several cells 111 coupled to the slave control units 140.

In an embodiment, the slave control units 140 is configured to: (1) obtain the measured system current value Iss broadcasted by the master control unit 150; (2) determine whether the abnormality occurring to the battery system 100 pertains to system abnormality or the detection abnormality according to the measured voltage value Vt, the measured temperature value Tt and the measured system current value Iss. Besides, examples of the measured system current value Iss include the detected value of the string current (such as system current Is) formed by serially connecting all unit battery groups 110 of the battery system 100.

The master control unit 150 and the slave control units 140 are connected in series through a communication interface such as RS485, CAN Bus or through wireless communication. In an embodiment, the master control unit 150 could broadcast to all slave control units 140 and request one or some of the slave control units 140 to report its detected information. When all slave control units 140 receive the request from the master control unit 150, only the one inquired by the master control unit 150 needs to report. Since anyone of the slave control units 140 could receive the information broadcasted by all elements on the communication transmission line (including the master control unit 150 and the remaining slave control units 140), any of the slave control units 140 and the master control unit 150 could obtain the information necessary for the calculation and determination of detection abnormality and system abnormality. Thus, any of the slave control units 140 not only could determine whether each cell 111 coupled to any of the slave control units 140 is abnormal but also could determine whether each cell 111 coupled to other slave control units 140 is abnormal.

As indicated in FIG. 1B, the protection method of the battery system 100 includes the following steps. In step S110, a measured system current value Iss of the unit battery groups 110 is measured by the current measuring unit 130. In step S120, the physical parameter values of voltage and temperature of each string of cells 111 of the unit battery groups 110 are measured by the voltage measurer and the temperature measurer of each slave control unit 140 connected thereto. In step S130, when the abnormality is determined according to the physical parameter value or the measured system current value Iss pertains to system abnormality, the main switch 120 is disconnected by the master control unit 150; when the abnormality is determined according to the physical parameter value or the measured system current value Iss pertains to detection abnormality, a corresponding processing procedure for processing detection abnormality is performed by the master control unit 150.

Several implementations of system abnormality and detection abnormality are exemplified below. When detection abnormality occurs, the slave control units 140 could perform a processing procedure for processing detection abnormality. For example, abnormal physical parameter values are ignored, that is, abnormal physical parameter values are not taken into consideration.

First Scenario of System Abnormality:

The slave control units 140 could determine whether the system is abnormal or not according to the temperature change of the cell 111. For example, the slave control units 140 are configured to: (1) determine whether the measured temperature value Tt of the measured cell 111′ increases dramatically within a unit of time or not; (2) determine whether the measured temperature value Tt of the cells 111″ adjacent to the measured cell 111′ synchronously increases dramatically or not when the measured temperature value Tt of the measured cell 111′ increases within a unit of time; (3) determine that the abnormality occurring to the battery system 100 pertains to system abnormality when the measured temperature value Tt of the cells 111″ adjacent to the measured cell 111′ synchronously increase dramatically.

As indicated in FIG. 2, let the physical parameter value be exemplified by temperature, then curve C11 represents the temperature change of the measured cell 111′, curves C12 and C13 respectively represent the temperature change of the adjacent cells 111″, curves C14 to C17 represent the temperature change of the normal cells 111. According to curves C11 to C17, it is determined that the temperature rise caused by the short-circuiting or failure of the measured cell 111′ pertains to system abnormality. Since the temperature rise of the measured cell 111′ also causes the temperature to rise in the adjacent cells 111″, the slave control units 140, according to the detected synchronous temperature rise of the measured cell 111′ and the adjacent cells 111″, determines that the measured battery system 100 has system abnormality. Meanwhile, the slave control units 140 inform the master control unit 150 through communication that the result of the determination indicates system abnormality, then the master control unit 150 disconnects to the main switch 120 and activates a protection mechanism to protect the system from over temperature.

Moreover, the measured cell 111′ of the present scenario could be any or each of all cells and is not limited by the designations of FIG. 1A.

For example, the measured cell 111′ could be selected from the cell with the highest temperature among a single unit battery group 110. That is, when the slave control units 140 determines the state of system abnormality according to the temperature change of the cell 111, the slave control units 140 could perform determination according to the measured cell 111′ with the largest measured temperature value Tt among the corresponding unit battery group 110. In another embodiment, the measured cell 111′ could be selected from the cell with the lowest temperature among a single unit battery group 110. When the slave control units 140 determines that the abnormality pertains to system abnormality, the master control unit 150 could activate a protection mechanism to protect the system from under temperature. In other embodiments, the measured cell 111′ could be selected from two cells 111 with the largest temperature difference among a single unit battery group 110. Detailed implementations are not limited to the said exemplifications.

Second Scenario of System Abnormality:

The slave control units 140 could determine whether the system is abnormal or not according to the voltage change of the cell 111. For example, the slave control units 140 is configured to: (1) determine whether the change in the measured voltage value Vt of the measured cell 111′ within a unit of time is over a limit value or not; (2) determine whether the measured system current value Iss synchronously varies with the measured voltage value Vt of the measured cell 111′ or not in comparison to the measured system current value Iss broadcasted by the master control unit 150 when the change in the measured voltage value Vt of the measured cell 111′ within a unit of time is over a limit value; (3) determine that the abnormality occurring to the battery system 100 pertains to system abnormality when the measured system current value Iss synchronously varies with the measured voltage value Vt of the measured cell 111′.

For more details, when the external device 10 of the battery system 100 (such as a motor) is short-circuited, the measured system current value Iss and the measured voltage value Vt will synchronously change dramatically. For example, the measured system current value Iss increases dramatically, and the measured voltage value Vt (or, string voltage) drops dramatically. Under such a circumstance, the main switch 120 must be immediately disconnected to avoid the battery system 100 being damaged due to short-circuiting. Therefore, the master control unit 150 determines the abnormality as system abnormality and directly activates a contingency mechanism to disconnect the main switch 120.

In an embodiment, the limit value exemplified by voltage value includes the voltage difference limit value of the change rate of string voltage estimated according to the largest current of the battery system 100, or the boundary value of the safety work range as specified in the specifications of each cell 111. For example, the largest tolerable charging voltage and the lowest tolerable discharging voltage of the cell 111 are used as limit values. The “limit value” exemplified by temperature includes the boundary value of the safety work range as specified in the specifications of each cell 111, for example, the highest temperature and the lowest temperature are used as limit values. The limit value exemplified by current includes the largest tolerable charging current in the charging stage and the discharging stage respectively. Furthermore, the measured cell 111′ of the present scenario could be any or each of all cells 111.

In an embodiment, the measured cell 111′ could be selected from the cell with the largest voltage among a single unit battery group 110. That is, when the slave control units 140 determines the state of system abnormality according to the voltage change of the cell 111, the slave control units 140 could perform determination according to the measured cell 111′ with the largest measured voltage value Vt among the corresponding unit battery group 110. In another embodiment, the measured cell 111′ could be selected from the cell with the lowest voltage among a single unit battery group 110. In other embodiments, the measured cell 111′ could be selected from the two cells 111 with the largest voltage difference among a single unit battery group 110. Detailed implementations are not limited to the said exemplifications.

In an embodiment, all the abnormalities not pertaining to system abnormality are determined as detection abnormality, but the embodiments of the present disclosure are not limited thereto. A number of scenarios of detection abnormality are disclosed below.

First Scenario of Detection Abnormality:

The master control unit 150 or the slave control units 140 could determine whether the detection is abnormal or not according to the voltage change of the cell 111. Whether the abnormality occurring to the battery system 100 pertains to detection abnormality or not could be determined according to the relationship among the measured system current value Iss, the measured voltage value Vt and the measured temperature value Tt. The system current value Iss is measured by the master control unit 150 or the current measuring unit 130. The voltage value Vt and the temperature value Tt of each cell 111 are measured by the slave control units 140.

For more details, when the battery system 100 is in a discharging state and the measured system current value Iss suddenly becomes zero but the measured voltage value Vt of each cell 111 in all unit battery groups 110 does not rise correspondingly, this indicates that the circuit or wire for detecting or transmitting the measured system current value Iss (such as the transmission line W1 of FIG. 1) is abnormal (such as having disconnection or poor contact) and such abnormality pertains to detection abnormality of current.

Second Scenario of Detection Abnormality:

The slave control units 140 determines whether the detected abnormality pertains to detection abnormality or not according to the measured temperature values Tt of the several cells 111 change synchronously. For example, the slave control units 140 are configured to: (1) determine whether the measured temperature value Tt′ of the measured cell 111′ increases dramatically within a unit of time or not; (2) determine whether the measured temperature value Tt″ of the cells 111″ adjacent to the measured cell 111′ synchronously increase dramatically or not when the measured temperature value TV of the measured cell 111′ within a unit of time increases dramatically; (3) determine the abnormality occurring to the battery system 100 pertains to detection abnormality when the measured temperature value Tt″ of adjacent cells 111″ does not synchronously increase dramatically.

For more details, when the measured temperature value Tt′ of the measured cell 111′ increases dramatically within a unit of time but the measured temperature value Tt of adjacent or remaining cells 111 does not synchronously increase dramatically within a unit of time, this indicates that the circuit or wire for detecting or transmitting the measured temperature value Tt′ of the measured cell 111′ is abnormal (such as having disconnection or poor contact) and such abnormality pertains to detection abnormality of temperature.

Third Scenario of Detection Abnormality:

The slave control units 140 could determine whether the detected abnormality pertains to detection abnormality or not according to the measured system current value Iss synchronously changes with the measured voltage value Vt of the corresponding cells 111. For example, the slave control units 140 is configured to: determine the abnormality occurring to the battery system 100 pertains to detection abnormality when the change in the measured voltage value Vt′ of the measured cell 111′ is inconsistent with the change in the measured voltage value Vt of another one of the corresponding cells 111 and the measured system current value Iss synchronously changes with the measured voltage value Vt of the another one of the corresponding cells 111.

For more details, when the change in the measured voltage value Vt′ of the measured cell 111′ is inconsistent with the change in the measured voltage value Vt of other cells 111, this indicates that the circuit or wire for detecting or transmitting the measured voltage value Vt′ of the measured cell 111′ is abnormal (such as having disconnection or poor contact) and such abnormality pertains to detection abnormality of voltage.

Fourth Scenario of Detection Abnormality:

The slave control units 140 could determine whether the detected abnormality pertains to detection abnormality or not according to the physical parameter value curve of the measured cell 111′ has an equivalent offset with respect to the physical parameter value curve of other cells 111. For example, the slave control units 140 is configured to: determine the abnormality occurring to the battery system 100 pertains to detection abnormality when the change in the physical parameter value of the measured cell 111′ has an equivalent offset with respect to the change in the physical parameter value of other cells 111. As indicated in FIG. 2, curves C21 and C22 have an equivalent offset with respect to normal physical parameter value curves C14 to C17 or the average physical parameter value curve of the cells 111. For more details, curve C21 has an upward offset, curve C22 has a downward offset, and both curves C21 and C22 indicate failure of the measurer measuring the said physical parameter. Therefore, the slave control units 140 determines the abnormality of the present scenario as a detection abnormality.

Fifth Scenario of Detection Abnormality:

As indicated in FIG. 2, the physical parameter value of curve C3 has a jittering change which indicates noises. The slave control units 140 could determine whether the system is abnormal or not according to the physical parameter value or the measured system current value Iss. When the system is in a normal state, the change in current will cause the voltage to change correspondingly, and the voltage and the current are interlinked. When the measured voltage value Vt′ of the measured cell 111′ and the measured system current value Iss are not interlinked, such a scenario is determined as detection abnormality. For example, when the system current Is is zero, the voltage should be stable. However, when the measured system current value Iss is zero but the measured voltage Vt′ of the measured cell 111′ has irregular jittering changes like curve C3, such scenario is determined as detection abnormality.

Sixth Scenario of Detection Abnormality:

The slave control units 140 could determine whether the system is abnormal or not according to the temperature change of the cell 111. For example, the slave control units 140 is configured to: determine the abnormality occurring to the battery system 100 pertains to detection abnormality when the measured temperature value Tt of the measured cell 111′ surges or plummets abruptly. As indicated in FIG. 2, the physical parameter value is exemplified by temperature, and curves C4 and C5 respectively represent the measured temperature value Tt obtained by one of the cells 111. As indicated in curve C4, when the measured temperature value Tt abruptly plummets to zero, this indicates that the temperature measurer of the cell 111 has detection abnormality, such as disconnection or malfunction, the slave control units 140 determine such scenario as detection abnormality. As indicated in curve C5, when the measured temperature value Tt surges abruptly, this indicates that the temperature measurer of the cell 111 has detection abnormality, such as short-circuiting or malfunction, and the slave control units 140 also determines such scenario as detection abnormality. For more details, since temperature change is normally slow, when the measured temperature value Tt changes abruptly, such abnormality normally pertains to detection abnormality. Additionally, when the physical parameter value relates to voltage or current, it is possible that the physical parameter value may plummet to 0 like curve C4, and the slave control units 140 will also determine such scenario as detection abnormality. It should be noted that the terms “surge” and “plummet” here are different from “increase dramatically” and “drop dramatically” in other embodiments. The terms “surge” and “plummet” refer to an abrupt change in temperature at an instant; the terms “increase dramatically” and “drop dramatically” refer to a substantial change in temperature over a period of time.

To summarize, any of the slave control units 140 could determine whether any cell 111 has the detection abnormality or the system abnormality according to the measured temperature value Tt and/or the measured voltage value Vt of any cell (such as the measured cell 111′) and/or the measured system current value Iss broadcasted by the master control unit 150. The master control unit 150 determines whether disconnect to the main switch 120 or not according to the determination result from slave control units 140. When detection abnormality occurs, the slave control units 140 and/or the master control unit 150 could ignore the physical parameter values relevant to the measured cells 111′. When system abnormality occurs, the master control unit 150 could disconnect to the main switch 120 to protect the battery system 100. In an embodiment, the master control unit 150 also could determine the type of protection mechanism, such as over-voltage protection or over-temperature protection, according to the determination result.

Seventh Scenario of Detection Abnormality:

Referring to FIG. 3, a schematic diagram of several slave control units 140 serially connected to a master control unit 150 according to an embodiment of the present disclosure is shown. The slave control units 140 are serially connected to the master control unit 150 through communication and include communication ports 140A and 140B respectively disposed at two opposite ends of the serially connected slave control units 140.

The master control unit 150 further includes a first communication switch 151, a second communication switch 152 and a communication control unit 153. The communication ports of the communication control unit 153 are respectively coupled to one end of the first communication switch 151 and one end of the second communication switch 152. In the communication architecture of FIG. 3, a master control unit 150 is serially connected to three slave control units 140, 140′ and 140″, but the disclosure is not limited thereto. The other end of the first communication switch 151 opposite to the end of the first communication switch 151 connected to the communication control unit 153 is coupled to the communication port 140A of the first slave control unit 140, and the first communication switch 151 is configured to: connect or disconnect the communication with the first slave control unit 140. The communication port 140A′ of the second slave control unit 140′ is coupled to the communication port 140B of the first slave control unit 140 to transmit the information of the second slave control unit 140′ to the communication port 140A of the first slave control unit 140 through the communication port 140B, then the information of the second slave control unit 140′ is further transmitted to the communication control unit 153 through the first communication switch 151. By the same analogy, the communication port 140A″ of the third slave control unit 140″ is coupled to the communication port 140B′ of the second slave control unit 140′ to transmit the information of the third slave control unit 140″ to the communication control unit 153 through the communication port 140A and the first communication switch 151. The communication port 140B″ of the third slave control unit 140″ is serially connected to the second communication switch 152 to transmit the information to the communication control unit 153. At a time point, only one of the communication switch 151 and 152 is connected, such that the first communication switch 151 and the second communication switch 152 will not be connected at the same time otherwise the communication signals generated by the communication control unit 153 will be interfered with. The first communication switch 151 and the second communication switch 152 are configured to connect the communication between the communication control unit 153 and all slave control units 140, wherein the first communication switch 151 is the main communication switch and the second communication switch 152 is the secondary communication switch. The communication control unit 153 is configured to: (1) determine whether the report signals of all slave control units 140 (such as measured voltage value Vt and/or the measured temperature value Tt) are completely received or not; and (2) alternately connect the first communication switch 151 and the second communication switch 152 to completely receive the report signals of the slave control units 140 when the report signals of all slave control units 140 are not completely received.

To put it in greater details, when the battery system 100 is in a normal state, only the first communication switch 151 needs to be connected, and the communication control unit 153 will completely obtain the report signals of all slave control units 140. However, when the communication line has abnormality, for example, when the coupling between the communication port 140B′ and 140A″ has abnormality, the communication control unit 153 could only receive the report signals of the first slave control unit 140 and the second slave control unit 140′ through the first communication switch 151 but cannot receive the report signal of the third slave control unit 140″. When this scenario occurs, the master control unit 153, in order to receive the report signal of the third slave control unit 140″, will disconnect to the first communication switch 151 but will connect the second communication switch 152 instead. Meanwhile, the information received by the communication control unit 153 through the second communication switch 152 only contains the report signal of the third slave control unit 140″. As the first communication switch 151 and the second communication switch 152 are alternately connected, the communication control unit 153 could receive the report signal of all slave control units 140 and could determine, according to the report information of the slave control units 140 received through the first communication switch 151 and the second communication switch 152 respectively, that the abnormality of the communication line occurs between the second slave control unit 140′ and the third slave control unit 140″.

In an embodiment, if the report information of all slave control units 140 cannot be completely obtained when the first communication switch 151 is connected, it could be determined that detection abnormality occurs, and such detection abnormality pertains to communication abnormality. When communication abnormality occurs, the following processing procedure for processing detection abnormality is performed. The master control unit 150 connect the second communication switch 152 to receive the report information of the slave control units 140 and alternately switch the communication loop corresponding to the first communication switch 151 and the second communication switch 152 to completely obtain the report information of all slave control units 140. In an embodiment, the communication control unit 153 could obtain the position of the communication abnormality according to the report information transmitted from the first communication switch 151 and the second communication switch 152.

In the present embodiment, communication control unit 153 is coupled to all slave control units 140 through the first communication switch 151 and the second communication switch 152. In other embodiments, the communication control unit 153 could be coupled to the slave control units 140 through a three-way switch. To put it in greater details, the three terminal ends of the three-way switch are respectively connected to the communication control unit 153, the communication port 140A and the communication port 140B. When the three-way switch is connected, the communication control unit 153 is connected to the slave control units 140 through only the communication port 140A or the communication port 140B, and the function disclosed in above embodiments still could be achieved.

Eighth Scenario of Detection Abnormality:

Referring to FIG. 4, a current change chart of an external device 10 providing power to a battery system 100 according to an embodiment of the present disclosure is shown. In the present embodiment, the external device 10 could be realized by a charger. When the external device 10 is electrically connected to the battery system 100, the master control unit 150 is further configured to: (1) request the external device 10 to provide a test current to the battery system 100; (2) determine whether the first absolute value of current difference ΔI₁ between the first test current value Iₜ₁ and the measured system current value I_{S1} of the battery system 100 is greater than an allowable current error or not; (3) determine whether a State of Charge (SOC) of the battery system 100 is equivalent to or higher than a safety level (such as 20%) or not, when the first absolute value of current difference ΔI₁ is greater than an allowable current error; (4) connect the main switch 120 when the SOC of the battery system 100 is lower than the safety level, such that the external device 10 could charge the battery system 100 until the SOC of the battery system 100 reaches the safety level; (5) disconnect the main switch 120 when the first absolute value of current difference ΔI₁ is greater than the allowable current error and the SOC of the battery system 100 is equivalent to or higher than the safety level. The first test current value Iₜ₁ refers to the current value measured by the external device 10, and the measured system current value I_{S1} refers to the current value measured by the current measuring unit 130 of the battery system 100. Additionally, when the absolute value of current difference ΔI₁ is less than the allowable current error, the external device 10 charges the battery system 100 in a normal state, for example, the external device 10 provides a charging current I_{C} to the battery system 100. The absolute value of current difference ΔI₁ is represented by =abs (Iₜ₁-I_{S1}), and the allowable error is less than 3%.

To put it in greater details, when the absolute value of current difference ΔI₁ is greater than the allowable current error, this indicates that the battery system 100 has detection abnormality of current, and the following processing procedure for processing current detection abnormality is performed. When the SOC of the battery system 100 is equivalent to or higher than the safety level, the master control unit 150 disconnects to the main switch 120 to avoid possible risks which would otherwise arise if the charging of the battery system 100 continues. In another embodiment, although the absolute value of current difference ΔI₁ is greater than the allowable current error, the SOC of the battery system 100 is lower than the safety level, and the following processing procedure for processing current detection abnormality is performed. The master control unit 150 keeps the main switch 120 in the conducting state, such that the external device 10 could continuously charge the battery system 100 until the SOC of the battery system 100 reaches the safety level or until the total voltage of the battery system 100 is higher than the safety level, hence avoiding the battery system 100 being damaged due to the SOC being too low. The “safety level” could be the SOC allowing the battery system 100 or the user to have sufficient time to perform a contingent mechanism.

Ninth Scenario of Detection Abnormality:

As indicated in FIG. 4, the master control unit 150 is further configured to: (1) request the external device 10 to provide a first test current to the battery system 100; (2) determine whether the first absolute value of current difference ΔI₁ between the first test current value Iₜ₁ of the first test current and the measured current value of the corresponding battery system I_{S1} is greater than an allowable current error or not; (3) request the external device 10 to provide a second test current to the battery system 100, wherein the second test current value Iₜ₂ of the second test current is substantially higher than the first test current value Iₜ₁; (4) determine whether the second absolute value of current difference ΔI₂ between the second test current value Iₜ₂ and the measured current value of the corresponding battery system I_{S2} is greater than the allowable current error or not; (5) further determine whether the SOC of the battery system 100 is equivalent to or higher than a safety level (such as 20%) or not when anyone of the first absolute value of current difference ΔI₁ and the second absolute value of current difference ΔI₂ is greater than the allowable current error; (6) connect the main switch 120 when the SOC of the battery system 100 is lower than the safety level, such that the external device 10 could charge the battery system 100 until the SOC of the battery system 100 reaches the safety level or until the total voltage of the battery system 100 is higher than the safety level; (7) disconnect the main switch 120 when anyone of the first absolute value of current difference ΔI₁ and the second absolute value of current difference ΔI₂ is greater than the allowable current error and the SOC of the battery system 100 is equivalent to or higher than the safety level. The first test current value Iₜ₁ and the second test current value Iₜ₂ refer to the current value measured by the external device 10, and the measured system current values I_{S1} and I_{S2} refer to the current values measured by the current measuring unit 130 of the battery system 100. Besides, when the first absolute value of current difference ΔI₁ and the second absolute value of current difference ΔI₂ both are less than the allowable current error, the external device 10 charges the battery system 100 in a normal state, for example, the external device 10 provides a charging current I_{C} to the battery system 100. In an embodiment, the charging current I_{C} could be in a range between the first test current value Iₜ₁ and the second test current value Iₜ₂, but the embodiments of the present disclosure are not limited thereto.

To put it in greater details, when the first absolute value of current difference ΔI₁ and the second absolute value of current difference ΔI₂ are greater than the allowable current error, this indicates that the battery system 100 has detection abnormality of current, and the following processing procedure for processing current detection abnormality is performed. When the SOC of the battery system 100 is equivalent to or higher than the safety level, the master control unit 150 disconnect to the main switch 120 to avoid possible risks which would otherwise arise if the battery system 100 continues to use the distorted current value. For example, the distorted current value may fail the current protection function of the battery system. In another embodiment, although the first absolute value of current difference ΔI₁ and the second absolute value of current difference ΔI₂ both are greater than the allowable current error, the SOC of the battery system 100 is lower than the safety level, and the following processing procedure for processing current detection abnormality is performed. The master control unit 150 keeps the main switch 120 in the conducting state, such that the external device 10 could continuously charge the battery system 100 until the SOC of the battery system 100 reaches the range of safety level or until the total voltage of the battery system 100 is higher than the safety level, hence avoiding the battery system 100 being damaged due to the SOC being too low. The “safety level” could be the SOC allowing the battery system 100 or the user to have sufficient time to perform a contingent mechanism.

As disclosed in the eighth and ninth scenarios of the detection abnormality when the external device 10 is electrically connected to the battery system 100, the master control unit 150 could determine whether detection abnormality of current occurs or not. When detection abnormality of current occurs and the SOC of the battery system 100 is lower than the safety level, the battery system 100 will be charged until the SOC reaches a safety level or until the total voltage of the battery system 100 is higher than the safety level, then the main switch 120 is disconnected. Moreover, when the absolute value of current difference is lower than the allowable current error, this indicates that no detection abnormality of current occurs, and the external device 10 could charge the battery system 10 in a normal state.

Tenth Scenario of Detection Abnormality:

Referring to FIG. 5, a schematic diagram of the slave control units 140 of FIG. 1A and the cell 111 connected thereto is shown. Each slave control unit 140 includes a first battery switch 141, a second battery switch 142, a slave voltage measurer 143, a comparison voltage measurer 144 and a slave controller 145. The first battery switch 141 and the second battery switch 142 are respectively connected or disconnected at two ends a and b of the measured cell 111′ of the cell 111. The slave voltage measurer 143 is electrically connected to the measured cell 111′ to measure the first measured voltage V1 of the measured cell 111′. The comparison voltage measurer 144 is electrically connected to the first battery switch 141 and the second battery switch 142 and adapts to measure the second measured voltage V2 of the measured cell 111′. The first measured voltage V1 is the voltage value of the measured cell 111′ measured by the slave voltage measurer 143, and the second measured voltage V2 is the voltage value of the same measured cell 111′ measured by the comparison voltage measurer 144. The slave controller 145 is coupled to the slave voltage measurer 143 and the comparison voltage measurer 144 to: (1) control the first battery switch 141 and the second battery switch 142, such that the measured cell 111′ could be electrically connected to the comparison voltage measurer 144; (2) determine whether an absolute value of voltage difference ΔV (ΔV=abs (V1-V2)) between the first measured voltage V1 of the measured cell 111′ and the second measured voltage V2 measured by the comparison voltage measurer 144 is greater than an allowable voltage error (such as 5 mV) or not; (3) determine that measurement abnormality of string voltage occurs and output a detection abnormality signal S1 to the master control unit 150 through the serially connected transmission line W1 when the absolute value of voltage difference ΔV is greater than an allowable voltage error. Here, “string voltage” is such as the voltage difference between the two ends a and b of the measured cell 111′.

The “the first measured voltage V1” and “the second measured voltage V2” are such as the voltages at the two ends a and b of the measured cell 111′. Furthermore, the measured cell 111′ of the present scenario could be any or each of all cells.

In an embodiment as indicated in FIG. 5, each slave control unit 140 includes several battery switching groups 146; each battery switching group 146 includes a first battery switch 141 and a second battery switch 142; and each cell 111 is electrically connected to a battery switching group 146. To put it in greater details, the two ends a and b of each cell 111 could be electrically connected to a first battery switch 141 and a second battery switch 142. The first battery switch 141 and the second battery switch 142 respectively could be connected or disconnected at the two ends a and b of each cell 111. The slave voltage measurer 143 is electrically connected to the cell 111 to measure the first measured voltage V1 of each cell 111. The comparison voltage measurer 144 is electrically connected to the first battery switch 141 and the second battery switch 142 and adapts to measure the second measured voltage V2 of each cell 111. The first measured voltage V1 is the voltage value of each cell 111 measured by the slave voltage measurer 143, and the second measured voltage V2 is the voltage value of each cell 111 measured by the comparison voltage measurer 144. The slave controller 145 is coupled to the slave voltage measurer 143 and the comparison voltage measurer 144 to: (1) alternately switch the battery switching groups 146, such that each cell 111 could be electrically connected to the comparison voltage measurer 144 in turn; (2) determine whether the absolute value of voltage difference ΔV between the first measured voltage V1 of each cell 111 and the second measured voltage V2 is greater than an allowable voltage error or not; (3) output a detection abnormality signal S1 to the master control unit 150 through the serially connected transmission line W1 when the absolute value of voltage difference ΔV is greater than the allowable voltage error.

In the present embodiment, the battery switching groups 146 are alternately switched, such that each cell 111 could be electrically connected to the comparison voltage measurer 144 in turn. That is, at a time point, only one of the battery switching groups 146 is connected and the remaining battery switching groups 146 are disconnected, such that a corresponding cell 111 is electrically connected to the comparison voltage measurer 144, and at the same time point only the voltage V of a cell 111 is transmitted to the comparison voltage measurer 144, hence avoiding the interference which would otherwise arise when several voltages V are transmitted to the comparison voltage measurer 144 at the same time.

As indicated in FIG. 5, each slave control unit 140 further includes a first busbar 147 and a second busbar 148. The first busbar 147 is connected to the first battery switch 141, that is, the first busbar 147 is connected to the anode of the to-be-the measured cell 111′. The second busbar 148 is connected to the second battery switch 142, that is, the second busbar 148 is connected to the cathode of the to-be-the measured cell 111′. The first busbar 147 and the second busbar 148 are electrically connected to the comparison voltage measurer 144. Thus, when the first battery switch 141 and the second battery switch 142 of the battery switching group 146 are connected, the cell 111, the first battery switch 141, the second battery switch 142, the first busbar 147, the second busbar 148 and the comparison voltage measurer 144 form a loop, through which the voltage V of the cell 111 could be transmitted to the comparison voltage measurer 144.

The determination of measurement abnormality of string voltage in the tenth scenario could be performed once after the external device 10 is activated. For example, let the external device 10 be a transportation tool (such as a vehicle). The determination of measurement abnormality of string voltage only needs to be performed once after the transportation tool is activated. The external device 10 could also be realized by a charging pile, and the determination of measurement abnormality of string voltage is performed before a vehicle is ready to be charged.

In an embodiment, the battery system 100 further includes an indicator 160 (illustrated FIG. 1A) coupled to the master control unit 150. When the battery system 100 in use has detection abnormality, the master control unit 150 could control the indicator 160 to output a detection abnormality alarm signal S2 (illustrated FIG. 1A). Examples of the indicator 160 include display monitor, light emitter and/or speaker. Examples of the detection abnormality alarm signal S2 include text, color light, symbol and/or alarm. The implementations of the indicator 160 and detection abnormality alarm signal S2 are not limited in the embodiments of the present disclosure, and any implementations of the indicator 160 and detection abnormality alarm signal S2 capable of warning the user of detection abnormality would do.

When the battery system 100 in use has detection abnormality, the master control unit 150 could ignore the detection abnormality and allow the battery system 100 to be in use as usual if the detection abnormality does not affect the safety and reliability of the battery system 100 (for example, when a temperature signal is detected to be abnormal, system safety still could be determined according to other temperature signals because there is a large amount of temperature signals available). However, if detection abnormality affects the safety and reliability of the battery system 100 (for example, voltage and current signals are detected to be abnormal), different measures will be taken depending on the following scenarios (1) and (2). In scenario (1) when the battery system 100 is not in use, the master control unit 150 disconnected to the switch to stop power supply until the abnormality is fixed. In scenario (2) when the battery system 100 is in use, to avoid the safety risk which may arise if the battery system 100 immediately stops power supply, the master control unit 150 may perform procedure (2-1) or (2-2). In procedure (2-1), the master control unit 150 reduces the voltage load (for example, the output of the system current value I_{S} is reduced when the string voltage measurement signal is found to be disconnected or offset when the user is driving). In procedure (2-2), the master control unit 150 activates a power-cut countdown timer mode (for example, the detection abnormality that the current is found to be 0 when the user is driving could be the disconnection of current measurement signal). During the power-cut countdown timer period, the user could guide the system safety to the shut-down state, then the battery system 100 enters the power-cut mode.

According to the battery system 100 and the protection method thereof disclosed in above embodiments of the present disclosure, through the design of decentralized computing, most of the calculations in the determination of abnormality state are performed by the slave control units 140, such that the workload of the master control unit 150 could be reduced. Meanwhile, through multiple comparisons of measurement, abnormality state could further be divided into two categories, namely, system abnormality and detection abnormality, to which different processing procedures are assigned, such that battery protection could have higher reliability.

While the disclosure has been described by way of example and in terms of the preferred embodiment (s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A battery system, comprising:
a plurality of unit battery groups, each comprising a plurality of cells serially connected to each other, and the plurality of unit battery groups connected in series with each other;
a main switch serially connected to the plurality of unit battery groups;
a current measuring unit serially connected to the plurality of unit battery groups to measure a measured system current value of the plurality of unit battery groups;
a plurality of slave control units electrically connected to the plurality of unit battery groups respectively, wherein each slave control unit is configured to obtain a physical parameter value of each cell in each unit battery group; and
a master control unit communicatively connected to the plurality of slave control units and configured to:
disconnect the main switch when abnormality determined according to the physical parameter value or the measured system current value pertains to a system abnormality; and
perform a processing procedure for a detection abnormality when the abnormality determined according to the physical parameter value or the measured system current value pertains to the detection abnormality.

2. The battery system of according to claim 1, wherein the master control unit and the plurality of slave control units are communicatively connected in series, and the plurality of slave control units further comprise a first slave control unit and a second slave control unit, which are respectively disposed at two opposite ends of the plurality of slave control units which connected in series; the master control unit further comprises:
a first communication switch coupled to the first slave control unit to connect or disconnect communication with the first slave control unit;
a second communication switch coupled to the second slave control unit to connect or disconnect communication with the second slave control unit; and
a communication control unit coupled to the first communication switch and the second communication switch to alternately connect the first communication switch and the second communication switch to receive all report signals of the plurality of slave control units.

3. The battery system of according to claim 1, wherein the master control unit is further configured to:
request a charger to provide a first test current to the battery system;
determine whether a first absolute value of current difference between a first test current value of the first test current and the measured system current value corresponding to the battery system is greater than an allowable current error or not; and
determine whether State Of Charge (SOC) of the battery system is equivalent to or higher than a safety level or not when the first absolute value of current difference is greater than the allowable current error;
connect the main switch when the SOC of the battery system is lower than the safety level, such that the charger could charge the battery system until the SOC of the battery system reaches the safety level; and
disconnect the main switch when the SOC of the battery system is equivalent to or higher than the safety level;
wherein the first test current value refers to a current value measured by the charger, and the measured system current value refers to a current value measured by the current measuring unit of the battery system.

4. The battery system according to claim 3, wherein the master control unit is further configured to:
request the charger to provide a second test current to the battery system, wherein the second test current is substantially higher than the first test current;
determine whether a second absolute value of current difference between a second test current value of the second test current and the measured system current value corresponding to the battery system is greater than the allowable current error or not;
determine whether SOC of the battery system is equivalent to or higher than the safety level or not when anyone of the first absolute value of current difference and the second absolute value of current difference is greater than the allowable current error;
connect the main switch when the SOC of the battery system is lower than the safety level, such that the charger charges the battery system until the SOC of the battery system reaches the safety level; and
disconnect the main switch when the SOC of the battery system is equivalent to or higher than the safety level;
wherein the second test current value refers to a current value measured by the charger.

5. The battery system of according to claim 1, wherein each slave control unit further comprises:
a first battery switch and a second battery switch respectively connected or disconnected at two ends of a measured cell of the plurality of cells;
a slave voltage measurer electrically connected to the measured cell to measure a first measured voltage of the measured cell;
a comparison voltage measurer electrically connected to the first battery switch and the second battery switch to measure a second measured voltage of the measured cell; and
a slave controller coupled to the slave voltage measurer and the comparison voltage measurer to:
control the first battery switch and the second battery switch, such that the measured cell is electrically connected to the comparison voltage measurer;
determine whether an absolute value of voltage difference between the first measured voltage of the measured cell and the second measured voltage measured by the comparison voltage measurer is greater than an allowable voltage error or not; and
output a detection abnormality signal to the master control unit when the absolute value of voltage difference is greater than the allowable voltage error;
wherein the first measured voltage is voltage value of the measured cell measured by the slave voltage measurer, and the second measured voltage is voltage value of the measured cell measured by the comparison voltage measurer.

6. The battery system of according to claim 1, wherein each slave control unit further comprises:
a plurality of battery switching groups, each comprising:
a first battery switch; and
a second battery switch, wherein each cell is electrically connected to the battery switching group, and the first battery switch and the second battery switch respectively are connected or disconnected at two ends of the cell;
a slave voltage measurer electrically connected to the plurality of cells to measure a first measured voltage of each cell;
a comparison voltage measurer electrically connected to the first battery switches and the second battery switches to measure a second measured voltage of each cell; and
a slave controller coupled to the slave voltage measurer and the comparison voltage measurer to:
alternately control the battery switching groups, such that each cell is electrically connected to the comparison voltage measurer in turn;
determine whether an absolute value of voltage difference between the first measured voltage and the second measured voltage of each cell is greater than an allowable voltage error or not; and
output a detection abnormality signal to the master control unit when the absolute value of voltage difference is greater than the allowable voltage error;
wherein the first measured voltage is voltage value of each cell measured by the slave voltage measurer, and the second measured voltage is voltage value of each cell measured by the comparison voltage measurer.

7. The battery system according to claim 6, wherein each slave control unit further comprises:
a first busbar connected to the first battery switches; and
a second busbar connected to the second battery switches;
wherein the first busbar and the second busbar are electrically connected to the comparison voltage measurer.

8. The battery system of according to claim 1, further comprising:
an indicator coupled to the master control unit to output a detection abnormality alarm signal when the detection abnormality occurs.

9. A protection method of a battery system, wherein the battery system is the battery system of according to claim 1, and the protection method comprises:
measuring the measured system current value of the plurality of unit battery groups by the current measuring unit;
measuring the physical parameter value of each cell in each unit battery group by each cell;
disconnecting the main switch by the master control unit when the abnormality determined according to the physical parameter value or the measured system current value pertains to the system abnormality; and
performing the processing procedure for the detection abnormality by the master control unit when the abnormality determined according to the physical parameter value or the measured system current value pertains to the detection abnormality.

10. The protection method according to claim 9, wherein the physical parameter value is a measured voltage value or a measured temperature value detected by each cell; the protection method further comprises:
obtaining the measured system current value by the plurality of slave control units;
determining, by the plurality of slave control units, whether the abnormality occurring to the battery system pertains to the system abnormality or the detection abnormality according to the measured voltage value, the measured temperature value and the measured system current value.

11. The protection method according to claim 10, further comprising:
determining, by the plurality of slave control units, whether the measured temperature value of a measured cell of the plurality of cells increases dramatically within a unit of time or not;
determining, by the plurality of slave control units, whether measured temperature values of the plurality of cells adjacent to the measured cell synchronously increase dramatically or not when the measured temperature value of the measured cell within the unit of time increases dramatically; and
determining, by the plurality of slave control units, that the abnormality occurring to the battery system pertains to the system abnormality when the measured temperature values of the plurality of cells adjacent to the measured cell synchronously increase dramatically.

12. The protection method according to claim 10, further comprising:
determining, by the plurality of slave control units, whether a change in the measured voltage value of a measured cell of the plurality of cells within a unit of time is over a limit value or not;
determining, by the plurality of slave control units, whether the measured system current value synchronously varies with the measured voltage value of the measured cell or not in comparison to the measured system current value broadcasted by the master control unit when the change in the measured voltage value of the measured cell within the unit of time is over the limit value; and
determining, by the plurality of slave control units, that the abnormality occurring to the battery system pertains to the system abnormality when the measured voltage value of the measured cell changes synchronously with the measured system current value.

13. The protection method according to claim 10, further comprising:
Determining, by the plurality of slave control units, that the abnormality occurring to the battery system pertains to the detection abnormality when the battery system is in a discharging state, the measured system current value suddenly becomes zero, and the measured voltage value of each cell does not have corresponding change.

14. The protection method according to claim 10, further comprising:
Determining, by the plurality of slave control units, whether the measured temperature value of a measured cell of the plurality of cells increases dramatically or not;
determining whether the measured temperature values of the plurality of cells adjacent to the measured cell synchronously increase dramatically or not when the measured temperature value of the measured cell increases dramatically; and
determining that the abnormality occurring to the battery system pertains to the detection abnormality when the measured temperature values of the plurality of cells adjacent to the measured cell do not synchronously increase dramatically.

15. The protection method according to claim 10, further comprising:
determining by the plurality of slave control units that the abnormality occurring to the battery system pertains to the detection abnormality when a change in the measured voltage value of a measured cell of the plurality of cells is inconsistent with the change in the measured voltage value of another one of the plurality of cells and the measured system current value synchronously varies with the measured voltage value of the another one of the plurality of cells.

16. The protection method according to claim 10, further comprising:
determining by the plurality of slave control units that the abnormality occurring to the battery system pertains to the detection abnormality when a change in the physical parameter value of a measured cell of the plurality of cells has an equivalent offset with respect to the change in the physical parameter value of other cells.

17. The protection method according to claim 10, further comprising:
determining by the plurality of slave control units that the abnormality occurring to the battery system pertains to the detection abnormality when the physical parameter value of a measured cell of the plurality of cells or the measured system current value is not interlinked and has irregular jittering changes.

18. The protection method according to claim 10, further comprising:
determining by the plurality of slave control units that the abnormality occurring to the battery system pertains to the detection abnormality when the measured temperature value of a measured cell of the plurality of cells surges or plummets abruptly.

19. The protection method according to claim 9, wherein the master control unit and the plurality of slave control units are communicatively connected in series; the plurality of slave control units further comprise a first slave control unit and a second slave control unit, which are respectively disposed at two opposite ends of the plurality of slave control units; the master control unit further comprises a first communication switch, a second communication switch and a communication control unit; the first communication switch is coupled to the first slave control unit; the second communication switch is coupled to the second slave control unit; and the communication control unit is coupled to the first communication switch and the second communication switch; the protection method further comprises:
connecting or disconnecting communication with the first slave control unit by the first communication switch;
connecting or disconnecting communication with the second slave control unit by the second communication switch; and
alternately connecting the first communication switch and the second communication switch by the communication control unit.

20. The protection method according to claim 9, further comprising:
requesting a charger to provide a first test current to the battery system by the master control unit;
determining whether a first absolute value of current difference between a first test current value of the first test current and the measured system current value of the battery system is greater than an allowable current error or not; and
determining by the master control unit whether a SOC of the battery system is equivalent to or higher than a safety level or not when the first absolute value of current difference is greater than the allowable current error;
connecting the main switch by the master control unit when the SOC of the battery system is lower than the safety level, such that the charger charges the battery system until the SOC of the battery system reaches the safety level; and
disconnecting the main switch by the master control unit when the SOC of the battery system is equivalent to or higher than the safety level;
wherein the first test current value refers to a current value measured by the charger, and the measured system current value refers to a current value measured by the current measuring unit of the battery system.

21. The protection method according to claim 20, further comprising:
requesting the charger to provide a second test current to the battery system by the master control unit, wherein the second test current is substantially higher than the first test current;
determining whether a second absolute value of current difference between a second test current value of the second test current and the measured system current value of the battery system is greater than the allowable current error or not;
determining by the master control unit whether a SOC of the battery system is equivalent to or higher than a safety level or not when anyone of the first absolute value of current difference and the second absolute value of current difference is greater than the allowable current error;
connecting the main switch by the master control unit when the SOC of the battery system is lower than the safety level, such that the charger charges the battery system until the SOC of the battery system reaches the safety level; and
disconnecting the main switch by the master control unit when the SOC of the battery system is equivalent to or higher than the safety level;
wherein the second test current value refers to a current value measured by the charger.

22. The protection method according to claim 14, further comprising:
ignoring the detection abnormality by the master control unit when the detection abnormality does not affect the safety and reliability of the battery system.

23. The protection method according to claim 9, further comprising:
disconnecting the main switch by the master control unit when the battery system is not in use with the detection abnormality.

24. The protection method according to claim 9, further comprising:
decreasing an output of a system current value by the master control unit when the battery system is in use with the detection abnormality.

25. The protection method according to claim 9, further comprising:
activating a power-cut countdown timer mode by the master control unit when the battery system is in use with the detection abnormality.
